(19) United States
(12) Patent Application Publication
(10) Pub. No.: US 2012/0104468 A1
(43) Pub. Date: May 3, 2012

(54) FABRICATING HIGH VOLTAGE TRANSISTORS IN A LOW VOLTAGE PROCESS

(75) Inventors: Yanjun Li, Shanghai (CN); Sen Zhang, Wuxi (CN)

(73) Assignee: O2MICRO, INC., Santa Clara, CA (US)

(21) Appl. No.: 13/236,537

(22) Filed: Sep. 19, 2011

(30) Foreign Application Priority Data
Nov. 3, 2010 (CN) 201010530071.4

(51) Int. Cl. H01L 29/80; H01L 21/8232; H01L 29/78; H01L 21/8234

(52) U.S. Cl. 257/285; 438/301; 438/186; 257/335; 257/E21.616; 257/E21.615; 257/E29.31; 257/E29.256

(57) ABSTRACT

Fabricating high voltage transistors includes forming a buried p-type implant on a p-substrate for each transistor, the transistor having a source side and a drain side, wherein the p-type implant is positioned adjacent the source and is configured to extend under a gate region; depositing a low doping epitaxial layer on the p-substrate and the p-type implant for each high voltage transistor, the low doping epitaxial layer extending from the source to the drain; forming an N-Well in the low doping epitaxial layer for each transistor, wherein the N-Well corresponds to a low voltage transistor N-Well fabricated using a low voltage transistor fabrication process; and forming a p-top diffusion region in or on the N-Well for each transistor, wherein the p-top diffusion region is configured to compensate for a dopant concentration of the N-Well at or near a surface of the N-Well opposing the substrate.

### BACKGROUND

In AC to DC conversion applications and/or other high voltage applications, high voltage laterally diffused metal oxide semiconductor (HV LDMOS) transistors and/or high voltage junction field effect (HV JFET) transistors may be used to convert relatively high voltages to relatively low voltages. For example, the HV LDMOS and/or HV JFET transistors may be used to convert the relatively high voltages (e.g., about 100 V to about 260 V and higher, with peak voltage near 400 V) to relatively low voltages (e.g., about 3 V to about 25 V) to power analog and/or digital circuits. In another example, the HV LDMOS and/or HV JFET transistors may be used as switching power transistors configured to drive a load. HV LDMOS and/or HV JFET may also be used in other applications, known to those skilled in the art.

In a typical high voltage semiconductor fabrication process, a high voltage N-drift region is formed on a low doping P-type substrate using epitaxial growth and/or high temperature diffusion. In a typical low voltage semiconductor fabrication process, a low voltage N-Well is formed on the P-type substrate. The high voltage N-drift region and low voltage N-Well have mutually exclusive properties. For example, the N-drift region is fabricated with a dopant dose between 1.0E12 (i.e., 1.0×10¹²) and 3.0E12 (i.e., 3.0×10¹²) atoms per cm² while the N-Well dopant dose is between 4.0E12 (i.e., 4.0×10¹²) and 1.2E13 (i.e., 1.2×10¹³) atoms per cm². Accordingly, the high voltage N-drift region may not be replaced by the low voltage N-Well in a typical semiconductor fabrication process. Instead, an additional N-drift layer may be added that may increase fabrication costs.

In addition, an N-drift junction depth is generally greater than 6.0 μm. Creating an N-drift junction with this depth generally requires an additional high temperature diffusion process. This additional high temperature diffusion process may detrimentally affect low voltage semiconductors, e.g., may cause threshold voltages to change.

### SUMMARY

In one aspect, there is disclosed a method for fabricating high voltage transistors. The method may include forming a buried p-type implant on a p-substrate for each high voltage transistor, wherein the each high voltage transistor has a source side and a drain side, and wherein the buried p-type implant is positioned adjacent the source side and is configured to extend under a gate region; depositing a low doping epitaxial layer on the p-substrate and the buried p-type implant for each high voltage transistor, wherein the low doping epitaxial layer extends from the source side to the drain side; forming an N-Well in at least a portion of the low doping epitaxial layer for each high voltage transistor, wherein the N-Well corresponds to a low voltage transistor N-Well fabricated using a low voltage transistor fabrication process; and forming a p-top diffusion region in or on a portion of the N-Well for each high voltage transistor, wherein the p-top diffusion region is configured to compensate for a dopant concentration of the N-Well at or near a surface of the N-Well opposing the substrate.

In another aspect, there is disclosed an apparatus. The apparatus may include a high voltage transistor structure having a source side and an opposing drain side. The high voltage transistor structure may include a buried p-type implant (“bury-p”) on a p-substrate, wherein the bury-p is positioned adjacent the source side; a N-Well on the p-substrate, wherein the N-Well extends from the drain side at least a portion of a distance to the source side; and a p-top diffusion region (“p-top”) in or on at least a portion of the N-Well opposing the p-substrate, wherein the p-top diffusion region is configured to compensate for a dopant concentration of the N-Well at or near a surface of the N-Well opposing the substrate.

### BRIEF DESCRIPTION OF DRAWINGS

Features and advantages of the claimed subject matter will be apparent from the following detailed description of embodiments consistent therewith, which description should be considered with reference to the accompanying drawings, wherein:

FIG. 1 is a section view of a HV LDMOS (high voltage lateral diffused metal oxide semiconductor field effect transistor) structure, consistent with the present disclosure;

FIG. 2 is a section view of a HV JFET (high voltage junction field effect transistor) structure, consistent with the present disclosure;

FIG. 3 is an exemplary flow chart illustrating process operations for fabricating the HV LDMOS and HV JFET transistors in a low voltage process consistent with the present disclosure;

FIGS. 4A through 4F depict section views of the HV LDMOS structure depicted in FIG. 1 after intermediate process operations, consistent with the present disclosure; and

FIGS. 5A through 5F depict section views of the HV JFET depicted in FIG. 2 after intermediate process operations, consistent with the present disclosure.

### DETAILED DESCRIPTION

Generally, the present disclosure relates to semiconductor fabrication and semiconductor apparatuses. A method is disclosed that allows fabrication of high voltage (HV) transistors using a low voltage (LV) process. The HV LDMOS and HV JFET transistor structures include features configured to accommodate the fabrication process and to enable operation at typical relatively high operating voltages, e.g., on the order of hundreds of volts. In particular, the N-drift region of the HV transistor is configured as a LV N-Well, i.e., is fabricated with dopant dose between 4.0E12 and 1.2E13 atoms per cm². A p-type diffusion region is formed on the N-Well, configured to compensate for the relatively high dopant dose of the N-Well. The p-type diffusion region is configured to decrease surface doping of N-Well and to form a double reduced surface field (RESURF) structure. For the HV LDMOS, the N-drift region corresponds to the LV N-Well and for the HV JFET, the N-drift region and channel correspond to the LV N-Well. In other words, the HV LDMOS and HV JFET share the same process layer N-Well as a typical low voltage MOS transistor.

The N-Well junction depth is less than or equal to about 5.0 μm, i.e., may be fabricated without an additional high temperature process. Fabricating the N-Well may not require an additional high temperature process that is detrimental to low voltage transistors. The HV transistor structures may include a plurality of metal field plates (e.g., drain, source, and/or gate field plates (regions)) configured to provide a desired carrier concentration gradient in the N-Well, as described herein. For example, the metal field plates may be configured to modulate carrier concentration in the N-Well and/or the p-type diffusion region at and/or near the drain, source and/or gate, as described herein.

Although the methods disclosed herein are described with respect to N-channel HV LDMOS transistors and JFETs, it should be understood that high voltage P-channel LDMOS transistors and JFETs may be fabricated as described herein, by providing appropriate regions with opposite doping type.

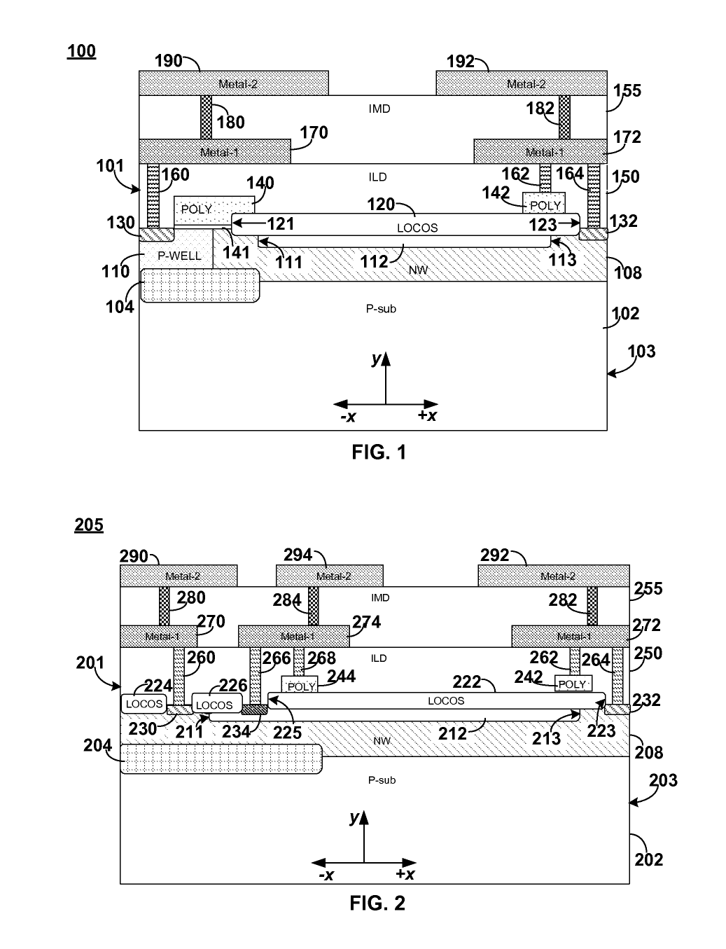

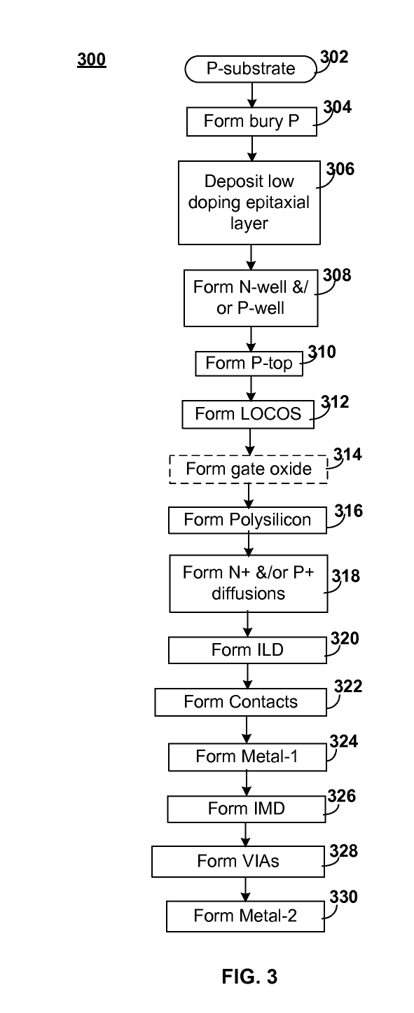

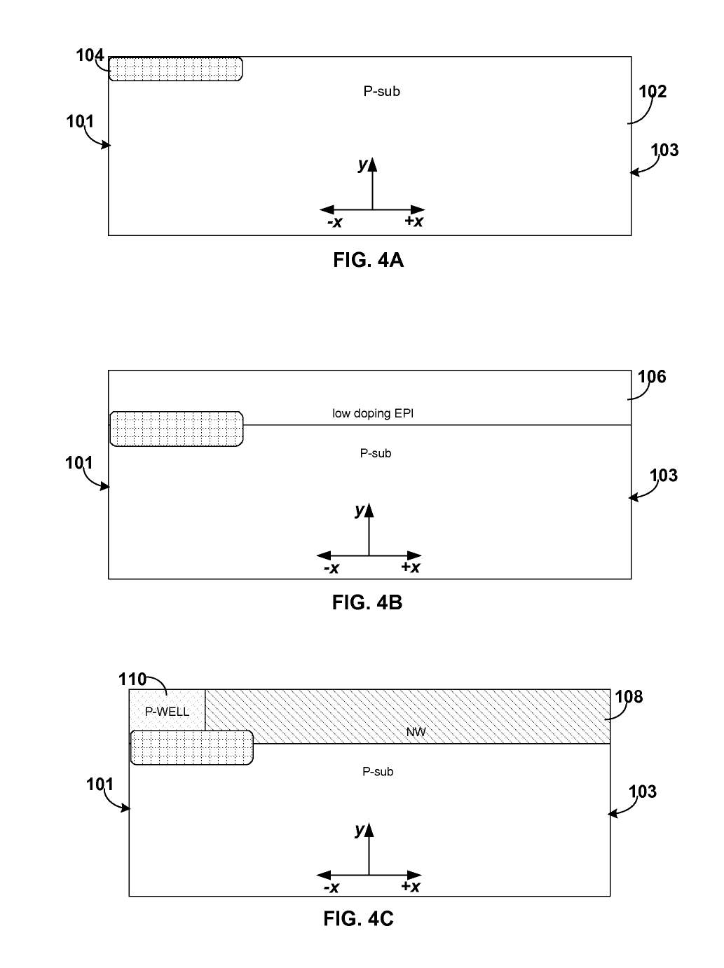

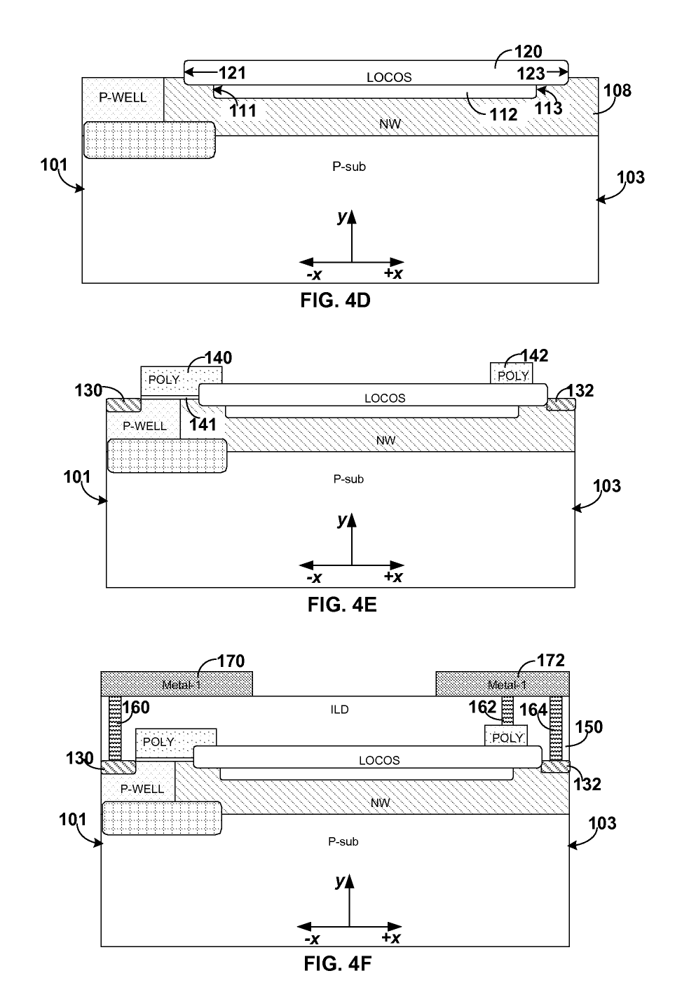

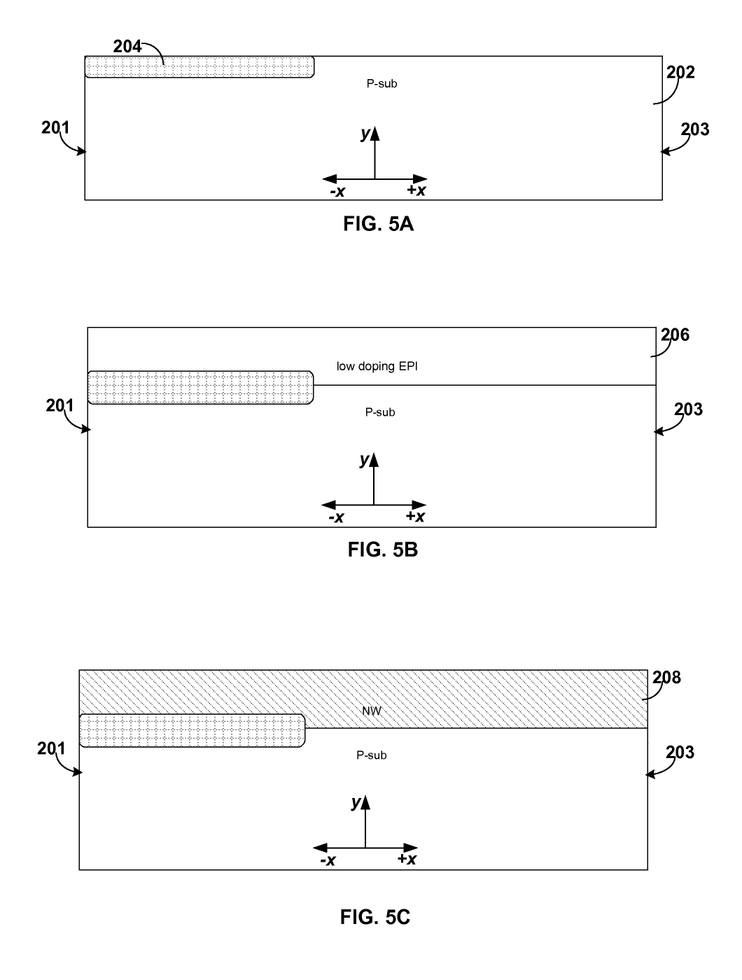

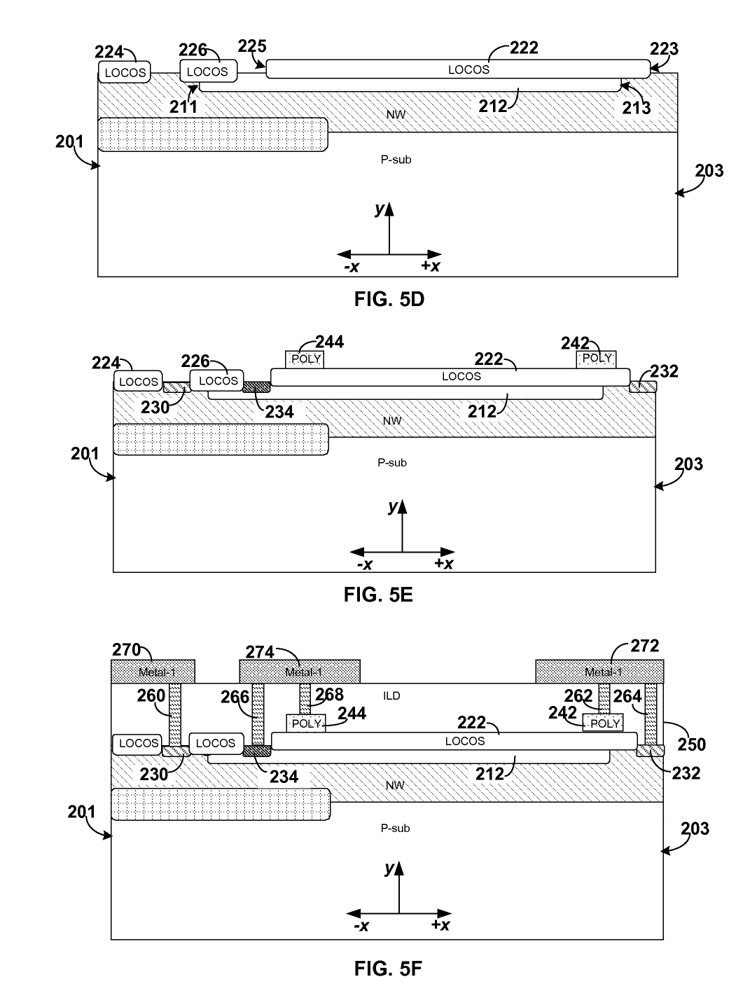

FIGS. 1 and 2 depict section views of a HV LDMOS transistor structure 100 and a HV JFET structure 205, respectively, consistent with the present disclosure. As will be appreciated by those skilled in the art, the illustrated cross-sections are simplified for clarity and ease of description. HV LDMOS and HV FET transistors may include other features and/or elements, known to those skilled in the art. As will be further appreciated by those skilled in the art, in a typical fabrication process, a plurality of transistors and/or other elements may be fabricated on a wafer. Although one transistor structure is illustrated in each figure, multiple transistors may be fabricated, in parallel, using a method consistent with the present disclosure. FIG. 3 is a process flow chart 300 illustrating process operations for fabricating the HV LDMOS and/or HV JFET in a low voltage transistor process. Low voltage (e.g., with operating voltages in the range of ones to tens of volts) transistors may be fabricated using at least a subset of the process operations depicted in flow chart 300. FIGS. 4A through 4F are section views of the HV LDMOS of FIG. 1 after intermediate processing operations. FIGS. 5A through 5F are section views of the HV FET structure of FIG. 2 after intermediate processing operations.

The section views of FIGS. 1 and 2, FIGS. 4A through 4F, and FIGS. 5A through 5F have been annotated with x and y axes. The x and y axes are in the plane of the paper and are provided for ease of reference, particularly when describing direction. The section views are further annotated with reference designators 101, 201 and 103, 203 corresponding to a source side and a drain side, respectively. The source side 101, 201 and drain side 103, 203 correspond to individual transistor structures. Multiple transistor structures may be fabricated on a wafer, in parallel, using a process consistent with the present disclosure. A negative x (−x) direction corresponds to a direction toward the source side 101, 201 and a positive (+x) direction corresponds to a direction toward the drain side 103, 203.

Process flow may begin 302 with provision of a p-substrate, e.g., p-substrate 102, 202. A buried p-type “bury-p” implant 104,204 may then be formed in or on the p-substrate 102, 202 at operation 304. The bury-p 104, 204 may be formed adjacent the source side 101, 201 of the HV LDMOS structure 100 and/or the HV JFET structure 205, respectively, and may extend in the +x direction under a gate region, as described herein. For example, the bury-p 104, 204 may be formed using ion implantation of a p-type dopant with a dose of about 1.0E12 to about 5.0E13 atoms per cm², e.g., boron. Other Group V p-type dopants may be used, as will be understood by those skilled in the art. In an HV LDMOS transistor, the bury-p 104 is configured to decrease an electric field formed between N-Well terminals near a channel, as will be understood by one skilled in the art. In an HV JFET transistor, the bury-p 204 is configured to modulate an HV pinch-off voltage. FIG. 4A depicts a section view of the HV LDMOS structure 100 and FIG. 5A depicts a section view of the HV JFET structure 205, after operation 304.

A low doping epitaxial layer 106, 206 may then be deposited at operation 306. For each transistor structure 100, 205, the low doping epitaxial layer may extend from the source side 101, 201 to the drain side 103, 203 of the transistor structure 100, 205. In actual processing, the low doping epitaxial layer may be deposited over an entire wafer surface. FIG. 4B depicts a section view of the HV LDMOS structure 100 and FIG. 5B depicts a section view of the HV JFET structure 205, after operation 306.

An N-Well and/or a P-Well may be formed in the epitaxial layer 106, 206 at operation 308. For the HV LDMOS structure 100, a P-Well 110 may be formed adjacent the source side 101 and may extend along a portion of the bury-p 104, in the +x direction. An N-Well 108 may be formed adjacent the P-Well 110 and may extend in the +x direction from the P-Well 110 to the drain side 103. In some embodiments, a portion of the N-Well may overlay the bury-p 104. For the HV JFET structure 205, an N-Well 208 may be formed in the epitaxial layer 206 at operation 308 and may extend from the source side 201 to the drain side 203, overlapping the bury-p 204. FIG. 4C depicts a section view of the HV LDMOS structure 100 and FIG. 5C depicts a section view of the HV JFET structure 205, after operation 308.

The N-Well 108, 208 is configured to replace a HV N-drift region, as described herein. For example, the N-Well 108, 208 may be formed using ion implantation with a dose in a range of about 4.0E12 to about 1.2E13 atoms per cm². As used herein, “atom” means atoms, molecules and/or their ions. Advantageously, this dose range corresponds to a dose range for an N-Well formed in a low voltage BCD (bipolar-CMOS-DMOS) process. The N-Well 108, 208 junction depth may be less than or equal to about 5.0 μm. In other words, the N-Well 108, 208 junction depth may be achieved without an additional high temperature process that may be detrimental to a LV MOS transistor structure.

A p-type diffusion region “p-top” 112, 212 may be formed in or on at least a portion of the N-Well 108, 208 at operation 310. The p-top 112, 212 includes a source end 111, 211 and a drain end 113, 213. The p-top 112, 212 may be oriented, in the x direction, so that the source end 111, 211 is generally closer to the source side 101, 201 of the HV LDMOS structure 100 and the HV JFET structure 205 and the drain end 113, 213 is generally closer to the drain side 103, 203. In an HV LDMOS structure 100, the p-top 112 is configured to overlap a drain metal plate and/or a source metal plate, as described herein. In an HV JFET structure 205, the p-top 212 is configured to form a gate junction, overlap at least a portion of bury-p 204 and overlap a drain metal plate, as described herein. A size of the p-top 112, 212 may depend on a desired drain operating voltage.

The p-top 112, 212 may be formed using ion implantation. The p-top 112, 212 is configured to compensate for the ion implantation dose range of the N-Well 108, 208 in a high voltage transistor structure. In other words, the ion implantation dose range of about 4.0E12 to about 1.2E13 atoms per cm², compatible with a process for fabricating low voltage transistor structures, is greater than the ion implantation dose range of a typical process for fabricating high voltage transistor structures. The p-top 112, 212 is configured to decrease a surface doping concentration of the N-Well 108, 208 at or near a surface of the N-Well 108, 208 opposing the substrate 102, 202. The p-top 112, 212 is configured to form a double reduced surface field (double RESURF) structure. Advantageously, the p-top 112, 212 may be formed without an additional high-temperature diffusion process.

One or more local oxidation of silicon (i.e., SiO₂) region(s) “LOCOS” may be formed at operation 312. For the HV LDMOS structure 100, LOCOS 120 may be formed. For the HV JFET structure 205, a plurality of LOCOS regions, including a gate-drain LOCOS 222, a source LOCOS 224 and a gate-source LOCOS 226 may be formed. For example, SiO₂ may be grown onto N-Well 108, 208 and/or p-top 112, 212. As will be understood by one skilled in the art, LOCOS 120, 222, 224, 226 may provide electrical isolation, (e.g., may act as an insulator), may be used as a dielectric, e.g., in a capacitor, and/or may provide a mask, e.g., configured to selectively allow dopants into region(s) not covered by the LOCOS and/or selectively prevent dopants into regions covered by the LOCOS.

For the HV LDMOS transistor structure 100, LOCOS 120 may include a source end 121 and a drain end 123. The source end 121 of LOCOS 120 is configured to extend beyond the source end 111 of the p-top 112 in the −x direction and the drain end 123 of the LOCOS 120 is configured to extend beyond the drain end 113 of the p-top 112 in the +x direction. FIG. 4D depicts a section view of the HV LDMOS structure after operations 310 and 312.

For the HV JFET structure 205, gate-drain LOCOS 222 includes a drain end 223 and a gate end 225. The drain end 223 of the gate-drain LOCOS 222 is configured to extend in the +x direction beyond the drain end 213 of the p-top 212. The source end 211 of the p-top 212 may extend in the −x direction beyond the gate end 225 of the gate-drain LOCOS 222. The gate-source LOCOS 226 may be positioned over the source end 211 of the p-top 212, may extend beyond the source end 211 of the p-top 212 in the −x direction and may overlay a portion of the p-top 212 adjacent the source end 211 in the +x direction. The source LOCOS 224 may extend in the +x direction from the source side 201. The source LOCOS 224, gate-source LOCOS 226, p-top 212 and at least a portion of gate-drain LOCOS 222 are configured to overlay at least a portion of the bury-p 204. FIG. 5D depicts a section view of the HV JFET structure 205 after operations 310 and 312.

For the HV LDMOS transistor structure 100, an oxide layer 141 may be formed on at least a portion of the P-Well 110 and at least a portion of the N-Well 108 at operation 314. The oxide layer 141 may be positioned adjacent the source end 121 of LOCOS 120 and may extend from the source end 121 in the −x direction toward the source side 101 of the HV LDMOS structure 100. The oxide layer 141 may be positioned to overlay a junction between the P-Well 110 and the N-Well 108 and may extend over a portion of the P-Well 110 and a portion of the N-Well 108. The oxide layer 141, e.g., “gate oxide”, is configured to provide a dielectric layer between a gate electrode and a conductive channel, as the gate is used to modulate the conductance of the channel between, e.g., source and drain.

One or more polycrystalline silicon regions (“Polysilicon” or “Poly”) may be formed at operation 316. For the HV LDMOS transistor structure 100, a gate poly region 140 may be formed on the oxide layer 141 and at least a portion of the LOCOS 120 adjacent the source end 121 of the LOCOS 120 and a drain Poly region 142 may be formed on at least a portion of the LOCOS 120 adjacent the drain end 123 of the LOCOS 120. The gate poly region 140 may extend, in the +x direction, from the source N+ diffusion 130, over the gate oxide region 141 and a portion of the LOCOS 120 adjacent the source end 121 of the LOCOS 120. The drain poly region 142 may be positioned such that it extends beyond the drain end 113 of the p-top 112 in the +x direction but does not extend beyond the drain end 123 of the LOCOS 120 in the +x direction.

For the HV JFET structure 205, a drain Poly region 242 and a gate Poly region 244 may be formed on the gate-drain LOCOS 222 at operation 316. The drain Poly region 242 may be positioned adjacent the drain end 223 of the gate-drain LOCOS 222 and may be positioned above the drain end 213 of the p-top 212. The gate Poly region 244 may be positioned adjacent the gate end 225 of the gate-drain LOCOS 222.

Operation 318 may include forming an N+ diffusion region and/or a P+ diffusion region. For the HV LDMOS transistor structure 100, a source N+ diffusion region 130 and a drain N+ diffusion region 132 may be formed on the P-Well 110 and N-Well 108, respectively, at operation 318. The source N+ diffusion region 130 may be positioned adjacent the source side 101 and the drain N+ diffusion region 132 may be positioned adjacent the drain side 103. For example, the source N+ diffusion region 130 and drain N+ diffusion region 132 may be formed with self-aligned implants. In other words, the gate poly region 140 may align the source N+ diffusion 130 and the LOCOS 120 may align the drain N+ diffusion 132. FIG. 4E depicts a section view of the HV LDMOS structure 100 after operations 314-318.

For the HV JFET structure 205, a source N+ diffusion region 230, a gate P+ diffusion region 234 and a drain N+ diffusion region 232 may be formed at operation 318. The source and drain N+ diffusion regions 230, 232 may be formed in or on the N-Well 208 and the gate P+ diffusion region 234 may be formed in or on the p-top 212. The diffusion regions 230, 232, 234 may be self-aligned by the LOCOS regions 222, 224 and 226. For example, the source N+ diffusion region 230 is aligned by the source LOCOS 224 and the gate-source LOCOS 226, the gate P+ diffusion region 234 is aligned by the gate-source LOCOS 226 and the gate-drain LOCOS 222 and the drain N+ diffusion 230 is aligned by the gate-drain LOCOS 222 and the drain side 203. The p-top 212 may extend in the −x direction from a location under the gate-drain LOCOS 222 adjacent the drain end 223 to a location under the gate-source LOCOS 226. FIG. 5E depicts a section view of the HV JFET structure 205 after operations 316 and 318.

As will be understood by one skilled in the art, dopant dose ranges may be indicated by a plus sign (+) or a minus sign (−), with + signifying dopant doses greater than those signified by −. For example, + corresponds to a dopant dose range of greater than or equal to about 1.0E15 atoms per cm² and − corresponds to a dopant dose range between about 1E12 to about 1E13 atoms per cm². For example, arsenic and/or phosphorous may be used as an N+ dopant, phosphorous may be used as an N− dopant, boron difluoride (BF2) and/or boron may be used as a P+ dopant and/or boron may be used as a P− dopant.

Operation 320 may include forming an inter-layer dielectric “ILD” 150, 250, extending in the +x direction from the source side 101, 201 of the structure 100, 205 to the drain side 103, 203 of the structure 100, 205. For example, the ILD 150, 250 may be formed of SiO₂ that may be deposited onto entire wafer surface using, e.g., chemical vapor deposition.

Operation 322 may include forming electrical contacts, in the ILD 150, 250 configured to connect the N+ and/or P+ diffusion regions and the drain and/or gate poly regions to Metal-1 regions. For the HV LDMOS transistor structure 100, a source contact 160 may be formed in the ILD 150, extending in the y direction, configured to connect the source N+ diffusion region 130 to a source Metal-1 region 170. A drain poly contact 162 may be formed in the ILD 150, extending in the y direction, configured to connect the drain poly region 142 to a drain Metal-1 region 172 and a drain N+ contact 164 may be formed in the ILD 150, extending in the y direction, configured to connect the drain N+ diffusion 132 to the drain Metal-1 region 172.

For the HV JFET structure 205, a source contact 260 may be formed in the ILD 250, extending in the y direction, configured to connect the source N+ diffusion region 230 to a source Metal-1 region 270. A drain poly contact 262 may be formed in the ILD 250, extending in the y direction, configured to connect the drain poly region 242 to a drain Metal-1 region 272 and a drain N+ via 264 may be formed in the ILD 250, extending in the y direction, configured to connect the drain N+ diffusion 232 to the drain Metal-1 region 272. A gate poly contact 268 may be formed in the ILD 250, extending in the y direction, configured to connect the gate poly region 244 to a gate Metal-1 region 274 and a gate P+ diffusion contact 266 may be formed in the ILD 250, extending in the y direction, configured to connect the gate P+ diffusion 234 to the gate Metal-1 region 274.

One or more Metal-1 regions may be formed at operation 324. For the HV LDMOS transistor structure 100, a source Metal-1 region 170 and a drain Metal-1 region 172 may be formed. The source Metal-1 region 170 may extend, in the +x direction, from the source side 101 over the source N+ diffusion 130, the oxide layer 141 and gate poly region 140, a portion of the LOCOS 120 adjacent the source end 121 of the LOCOS 120 and a portion of the p-top 112 adjacent the source end 111 of the p-top 112. The drain Metal-1 region 172 may extend, in the −x direction, from the drain side 103 over the drain N+ diffusion 132, the drain poly region 142, a portion of the LOCOS 120 adjacent the drain end 123 of the LOCOS 120 and a portion of the p-top 112 adjacent the drain end 113 of the p-top 112. FIG. 4F depicts a section view of the HV LDMOS structure after operations 320, 322, 324.

For the HV JFET structure 205, a source Metal-1 region 270, a drain Metal-1 region 272 and a gate Metal-1 region 274 may be formed on the ILD 250. The source Metal-1 region 270 may extend, in the +x direction, from the source side 201. The drain Metal-1 region 272 may extend, in the −x direction, from the drain side 203 over the drain N+ diffusion 232, the drain poly region 242, a portion of the gate-drain LOCOS 222 adjacent the drain end 223 and a portion of the p-top 212 adjacent the drain end 213. The gate Metal-1 region 274 may extend over the gate P+ diffusion region 234, a portion of the gate-drain LOCOS 222 adjacent the gate end 225 and including the gate end 225, and gate poly region 244 and beyond the gate poly region 244 in the +x direction. FIG. 5F depicts a section view of the HV JFET structure 205 after operations 320, 322, 324.

Operation 326 may include forming an inter-metal dielectric “IMD” 155, 255 extending in the +x direction from the source side 101, 201 of the structure 100, 205 to the drain side 103, 203. For example, the IMD 155, 255 may be formed of SiO₂ that may be deposited onto entire wafer surface using, e.g., chemical vapor deposition.

Operation 328 may include forming electrical vias, extending in the y direction configured to connect each Metal-1 region to a corresponding Metal-2 region. For the HV LDMOS transistor structure 100, a source metal via 180 may be formed in the IMD 155, extending in the y direction, configured to connect the source Metal-1 region 170 to a source Metal-2 region 190. A drain metal via 182 may be formed in the IMD 155, extending in the y direction, configured to connect the drain Metal-1 region 172 and a drain Metal-2 region 192.

For the HV JFET structure 205, electrical vias, may be formed in the IMD 255, extending in the y direction configured to connect each Metal-2 region to a corresponding Metal-1 region. For the HV JFET structure 205, a source metal via 280 may be formed in the IMD 255, configured to connect the source Metal-1 region 270 to the source Metal-2 region 290. A drain metal via 282 may be formed in the IMD 255 configured to connect the drain Metal-1 region 272 to the drain Metal-2 region 292. A gate metal via 284 may be formed in the IMD 255 configured to connect the gate Metal-1 region 274 and the gate Metal-2 region 294.

One or more Metal-2 regions may be formed at operation 330. For the HV LDMOS transistor structure 100, a source Metal-2 region 190 and a drain Metal-2 region 192 may be formed on the IMD 250. The source Metal-2 region 190 may extend, in the +x direction, from the source side 101 over the source Metal-1 region 170, a portion of the LOCOS 120 adjacent the source end 121 and a portion of the p-top 112 adjacent the source end 111. For example, the source Metal-2 region 190 may extend from the source side 101 to beyond the source Metal-1 region 170 in the +x direction. The drain Metal-2 region 192 may extend, in the −x direction, from the drain side 103 over the drain Metal-1 region 172, a portion of the LOCOS 120 adjacent the drain end 123 and a portion of the p-top 112 adjacent the drain end 113. For example, the drain Metal-2 region 192 may extend from the drain side 103 to beyond the drain Metal-1 region 172 in the −x direction. FIG. 1 depicts a section view of the HV LDMOS structure 100 after operations 326, 328, 330.

For the HV JFET structure 205, a source Metal-2 region 290, a drain Metal-2 region 292 and a gate Metal-2 region 294 may be formed on the IMD 255. The source Metal-2 region 290 may extend, in the +x direction, from the source side 201. The drain Metal-2 region 292 may extend, in the −x direction, from the drain side 203 over the drain Metal-1 region 272, a portion of the gate-drain LOCOS 222 adjacent the drain end 223 and a portion of the p-top 212 adjacent the drain end 213. The drain Metal-2 region 290 may extend from the drain side 203 to beyond the drain Metal-1 region 272 in the −x direction. The gate Metal-2 region 294 may extend over a portion of the gate Metal-1 region 274 and may extend beyond the gate Metal-1 region 274 in the +x direction. The gate Metal-2 region 294 may extend from gate Metal-1 region 274 over a portion of p-top 212 and a portion of gate-drain LOCOS 222 adjacent the gate end 225. FIG. 2 depicts a section view of the HV JFET structure 205 after operations 326, 328, 330.

For an HV LDMOS transistor consistent with the present disclosure, the poly regions 140, 142, Metal-1 regions 170, 172 and Metal-2 regions 190, 192 are configured to modulate carrier concentration in the N-Well 108. As used herein, “carriers” mean charge carriers and may therefore be holes and/or electrons. In operation, a relatively high potential difference may be applied between the source and drain of the LDMOS transistor, resulting in a voltage gradient in the N-Well 108 between the source side 101 and the drain side 103. As will be understood by those skilled in the art, in order to sustain the relatively high drain voltage, the N-Well 108 should be fully depleted of carriers.

Carriers in the N-Well 108 may be coupled (i.e., depleted) by carriers in the P-Well 110, bury-p 104, p-substrate 102 and/or the p-top 112. For example, adjacent the source side 101, N-Well 108 potential may be relatively low. In this region carriers in the p-substrate 102 may couple relatively few carriers in the N-Well 108, meanwhile, because p-top dose is constant, p-top coupled N-Well carriers is constant. As a result, relatively more carriers in the N-Well 108 may be coupled by carriers in the P-Well 110 and bury-p 104. If the carrier concentration in the N-Well 108 is high enough, coupling of carriers in the N-Well 108 may cause early breakdown to P-Well 110 and/or the bury-p 104. One option for preventing breakdown includes decreasing carrier concentration in the N-Well 108 by decreasing the implant dose but decreasing the implant dose may then decrease current carrying capacity of the LDMOS transistor.

With respect to the drain side 103, the potential of the N-Well 108 increases in the +x direction, i.e., toward the drain side 103. As the potential of the N-Well 108 increases, carriers in the p-substrate 102 may couple relatively more carriers in the N-Well 108 and relatively fewer carriers in the N-Well 108 may be coupled by carriers in the P-Well 110 and the bury-p 104. For example, adjacent the drain side 103, N-Well potential may be relatively high. In this region, carriers in the p-substrate 102 may couple a relatively high number of carriers in the N-Well 108. As a result, insufficient carriers may be available for coupling to carriers in the p-top 112, P-Well 110 and/or source Metal-1 region 170.

Advantageously, the amount of coupling (i.e., depletion of carriers in the N-Well 108) and effective carrier concentration in the N-Well 108 between the source side 101 and the drain side 103 may be modulated by the poly regions 140, 142, Metal-1 regions 170, 172 and Metal-2 regions 190, 192, without decreasing the implant dose. For example, the gate Poly region 140, source Metal-1 region 170 and source Metal-2 region 190 are configured to modulate N-Well 108 depletion and effective carrier concentration in the N-Well 108 adjacent the source side 101. In other words, for the HV LDMOS 110, under the gate Poly region 140, the field oxide 141 thickness is relatively thin allowing relatively significant depletion of carriers in the N-Well 108 under the gate Poly region 140 and, correspondingly, a decrease in effective carrier concentration in the N-Well 108. Under the source Metal-1 region 170, the ILD 150 is relatively thicker than the field oxide 141 resulting in a moderate depletion of carriers in the N-Well 108, i.e., under the Metal-1 region 170 not also under the gate poly region 140. Under the source Metal-2 region 190, the IMD 155 and ILD 150 are relatively thicker than both the ILD 150 and the field oxide 141 resulting in a lesser depletion of carriers in the N-Well 108 under the source Metal-2 region 190 not also under the source Metal-1 region 170. Accordingly, the gate poly region 140, source Metal-1 region 170 and source Metal-2 region 190 are configured to provide a continuously modulated depletion of carriers in the N-Well 108 adjacent the source side 101, e.g., extending from the source side in the +x direction to near the end of the Metal-2 region 190 away from the source side 101.

The drain poly region 142, drain Metal-1 region 172 and drain Metal-2 region 192 are configured to modulate the p-top 112 carrier depletion and the N-Well 108 effective carrier concentration adjacent the drain side 103. The drain voltage may be relatively high, accordingly, the voltage of the drain poly region 142 may also be relatively high. The LOCOS 120 under the drain poly region 142 may be relatively thin (e.g., compared to a thickness of the ILD 150 (in the y direction) and/or a thickness of the IMD 155 (in the y direction)). As a result, the drain poly region 142 may couple (deplete) a relatively significant number of carriers from the p-top 112. Accordingly, fewer carriers may be available in the p-top 112 for coupling carriers in the N-Well 108 adjacent the drain side 103. Since fewer carriers in the N-Well 108 may be coupled by carriers in the p-top 112, the N-Well 108 may have a higher effective carrier concentration for coupling to P-substrate, source-side PWELL adjacent the drain side 103.

The drain Metal-1 region 172 and drain poly region 142 may be at the same potential. Under the drain Metal-1 region 172 (i.e., between the drain Metal-1 region 172 and the p-top 112), a dielectric includes the ILD 150 and LOCOS 120 resulting in a thicker dielectric than the LOCOS 120 alone. The drain Metal-1 region 172 may moderately couple (deplete) carriers in the p-top 112 under the drain Metal-1 region 172 not also under the drain poly region 142. As a result, the corresponding effective carrier concentration in the N-Well may be moderately increased. Similarly, under the drain Metal-2 region 192, a dielectric includes IMD 155, ILD 150 and LOCOS 120 resulting in a thicker dielectric than between the drain Metal-1 region 172 and the p-top 112. The drain Metal-2 region 192 may couple (deplete) fewer carriers in the p-top under the drain Metal-2 192 not also under the drain Metal-1 172 relative to the depletion of carriers in the p-top 112 due to drain Metal-1 region 172. As a result, the corresponding effective carrier concentration in the N-Well 108 may be increased. This increase in effective carrier concentration in the N-Well 108 may be less than the increase in effective carrier concentration in the N-Well 108 under the drain Metal-1 region 172. Accordingly, the drain poly region 142, drain Metal-1 region 172 and drain Metal-2 region 192 may provide a continuously modulated depletion of carriers in the p-top 112 and a corresponding continuously modulated carrier concentration in the N-Well 108, adjacent the drain side 103.

Similarly, for the HV JFET structure 205, gate poly region 244, gate Metal-1 region 274 and gate Metal-2 region 294 are configured to modulate N-Well 208 depletion and effective carrier concentration in the N-Well 208 adjacent the gate P+ diffusion 234 in the +x direction. The drain poly 242, drain Metal-1 region 272 and drain Metal-2 region 292 are configured to modulate the p-top 212 carrier depletion and the N-Well 208 effective carrier concentration adjacent the drain side 203.

Of course, while FIG. 3 depicts exemplary operations according to some embodiments, it is to be understood that in other embodiments all of the operations depicted in FIG. 3 may not be necessary. Indeed, it is fully contemplated herein that other embodiments of the present disclosure may include sub-combinations of the operations depicted in FIG. 3 and/or additional operations. Thus, claims directed to features and/or operations that are not exactly shown in one drawing are deemed within the scope and content of the present disclosure.

Accordingly, there has been described herein a process for manufacturing HV LDMOS and HV JFET transistor structures using low voltage transistor fabrication process operations. In particular, the N-drift regions of the HV transistors are configured as LV N-Wells, i.e., fabricated with dopant dose between 4.0E12 and 1.2E13 atoms per cm². There has been further described herein HV transistor structures including N-Wells, consistent with the present disclosure. The transistor structures may include a bury-p region formed on the p-substrate. A p-type diffusion region may be formed on the N-Well, configured to compensate for the relatively high dopant dose of the N-Well. The p-type diffusion region is configured to decrease surface doping of N-Well and to form a double reduced surface field (RESURF) structure. Metal field plates, e.g., Metal-1 regions and Metal-2 regions, may be included and are configured to provide modulation of carrier concentrations in the N-Well and/or the p-top between the drain and source and/or gate terminals.

“Circuitry”, as used in any embodiment herein, may comprise, for example, singly or in any combination, hardwired circuitry, programmable circuitry, state machine circuitry, and/or firmware that stores instructions executed by programmable circuitry.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

What is claimed is:

1. A method for fabricating high voltage transistors, the method comprising:
forming a buried p-type implant on a p-substrate for each high voltage transistor, wherein the each high voltage transistor has a source side and a drain side, and wherein the buried p-type implant is positioned adjacent the source side and is configured to extend under a gate region;
depositing a low doping epitaxial layer on the p-substrate and the buried p-type implant for each high voltage transistor, wherein the low doping epitaxial layer extends from the source side to the drain side;
forming an N-Well in at least a portion of the low doping epitaxial layer for each high voltage transistor, wherein the N-Well corresponds to a low voltage transistor N-Well fabricated using a low voltage transistor fabrication process; and
forming a p-top diffusion region in or on a portion of the N-Well for each high voltage transistor, wherein the p-top diffusion region is configured to compensate for a dopant concentration of the N-Well at or near a surface of the N-Well opposing the substrate.

2. The method of claim 1 wherein the low voltage process comprises using a dopant dose between about 4E12 and about 1.2E13 atoms per cm² to form the N-Well.

3. The method of claim 1, further comprising:
for each high voltage transistor:
forming a source Metal-1 region extending from the source side over at least a portion of the N-Well; and
forming a drain Metal-1 region extending from the drain side over at least a portion of the p-top diffusion region.

4. The method of claim 3 further comprising:
for each high voltage transistor:
forming a source Metal-2 region extending from the source side toward the drain side to beyond the source Metal-1 region and connecting the source Metal-2 region to the source Metal-1 region, wherein the source Metal-1 region and source Metal-2 region are configured to modulate carrier concentration in the N-Well adjacent the source side; and
forming a drain Metal-2 region extending from the drain side toward the source side to beyond the drain Metal-1 region and connecting the drain Metal-2 region to the drain Metal-1 region, wherein the drain Metal-1 region and drain Metal-2 region are configured to modulate carrier concentration in at least one of the N-Well and the p-top adjacent the drain side.

5. The method of claim 1 wherein at least one high voltage transistor is a high voltage junction field effect transistor (HV JFET) and the p-top overlaps at least a portion of the buried p-type implant and further comprising forming the gate region in or on the p-top diffusion region of each HV JFET.

6. The method of claim 1 wherein at least one high voltage transistor is a high voltage laterally diffused metal oxide semiconductor (HV LDMOS) transistor and further comprising forming a P-Well on the buried p-type implant extending from the source side to the first N-Well of each HV LDMOS transistor.

7. The method of claim 1, further comprising:
for each high voltage transistor:
forming a gate Metal-1 region extending over a gate diffusion region and extending over at least a portion of the N-Well and at least a portion of the p-top diffusion region toward the drain side; and
forming a drain Metal-1 region extending from the drain side over at least a portion of the N-Well and at least a portion of the p-top diffusion region.

8. The method of claim 7 further comprising:
for each high voltage transistor:
forming a gate Metal-2 region extending over at least a portion of the gate Metal-1 region to beyond the gate Metal-1 region toward the drain side and connecting the gate Metal-2 region to the gate Metal-1 region, wherein the gate Metal-1 region and gate Metal-2 region are configured to modulate carrier concentration in the N-Well adjacent the gate diffusion region toward the drain side; and
forming a drain Metal-2 region extending from the drain side toward the source side to beyond the drain Metal-1 region and connecting the drain Metal-2 region to the drain Metal-1 region, wherein the drain Metal-1 region and drain Metal-2 region are configured to modulate carrier concentration in at least one of the N-Well and the p-top adjacent the drain side.

9. An apparatus comprising:
a high voltage transistor structure having a source side and an opposing drain side, the high voltage transistor structure comprising:
a buried p-type implant (“bury-p”) on a p-substrate, wherein the bury-p is positioned adjacent the source side;
a N-Well on the p-substrate, wherein the N-Well extends from the drain side at least a portion of a distance to the source side; and
a p-top diffusion region (“p-top”) in or on at least a portion of the N-Well opposing the p-substrate, wherein the p-top diffusion region is configured to compensate for a dopant concentration of the N-Well at or near a surface of the N-Well opposing the substrate.

10. The apparatus of claim 9 wherein the N-Well corresponds to a dopant dose between about 4E12 and about 1.2E13 atoms per cm².

11. The apparatus of claim 9 further comprising:
a source Metal-1 region wherein the source Metal-1 region extends from the source side over at least a portion of the N-Well and is configured to modulate N-Well depletion and effective carrier concentration in the N-Well adjacent the source side; and
a drain Metal-1 region wherein the drain Metal-1 region extends from the drain side over at least a portion of the N-Well and at least a portion of the p-top and is configured to modulate p-top carrier depletion and N-Well effective carrier concentration adjacent the drain side.

12. The apparatus of claim 11 further comprising:
a source Metal-2 region coupled to the source Metal-1 region, wherein the source Metal-2 region extends from the source side toward the drain side to beyond the source Metal-1 region; and
a drain Metal-2 region coupled to the drain Metal-1 region, wherein the drain Metal-2 region extends from the drain side toward the source side to beyond the drain Metal-1 region,
wherein the source Metal-1 region and source Metal-2 region are configured to provide a continuously modulated depletion of carriers in the N-Well adjacent the source side and the drain Metal-1 region and drain Metal-2 region are configured to provide a continuously modulated depletion of carriers in the p-top and a corresponding continuously modulated carrier concentration in the N-Well adjacent the drain side.

13. The apparatus of claim 9 wherein the high voltage transistor structure is a high voltage junction field effect transistor (HV JFET) structure.

14. The apparatus of claim 13 further comprising:
a gate Metal-1 region wherein the gate Metal-1 region is positioned between the source Metal-1 region and the drain Metal-1 region and extends over a portion of the p-top; and
a gate Metal-2 region coupled to the gate Metal-1 region, wherein the gate Metal-2 region extends over a portion of the gate Metal-1 region and extends beyond the gate Metal-1 region towards the drain side.

15. The apparatus of claim 9 wherein the high voltage transistor structure is a high voltage laterally diffused metal oxide semiconductor (HV LDMOS) transistor structure and further comprises a P-Well on the bury-p and extending from the source side to the N-Well.

16. The apparatus of claim 9 wherein an N-Well junction depth is less than or equal to 5.0 micrometers (μm).

17. The apparatus of claim 9, further comprising:
a gate Metal-1 region extending over a gate diffusion region and extending over at least a portion of the N-Well and at least a portion of the p-top diffusion region toward the drain side, wherein the gate Metal-1 region is configured to modulate the N-Well depletion and effective carrier concentration in the N-Well adjacent the gate diffusion region; and
a drain Metal-1 region wherein the drain Metal-1 region extends from the drain side over at least a portion of the N-Well and at least a portion of the p-top and is configured to modulate p-top carrier depletion and N-Well effective carrier concentration adjacent the drain side.

18. The apparatus of claim 17 further comprising:
a gate Metal-2 region extending over at least a portion of the gate Metal-1 region to beyond the gate Metal-1 region toward the drain side and connecting the gate Metal-2 region to the gate Metal-1 region; and
a drain Metal-2 region coupled to the drain Metal-1 region, wherein the drain Metal-2 region extends from the drain side toward the source side to beyond the drain Metal-1 region,
wherein the gate Metal-1 region and gate Metal-2 region are configured to provide a continuously modulated depletion of carriers in the N-Well adjacent the gate diffusion region toward the drain side and the drain Metal-1 region and drain Metal-2 region are configured to provide a continuously modulated depletion of carriers in the p-top and a corresponding continuously modulated carrier concentration in the N-Well adjacent the drain side.
